(19) United States
(12) Patent Application Publication
(10) Pub. No.: US 2025/0201304 A1
(43) Pub. Date: Jun. 19, 2025

(54) PROBABILISTIC STORAGE ELEMENTS WITH FIXED MAXIMUM CAPACITY

(71) Applicant: Hart Felix LLC, Sarasota, FL (US)

(72) Inventor: Gerard E. Felix, Sarasota, FL (US)

(21) Appl. No.: 18/543,771

(22) Filed: Dec. 18, 2023

(51) Int. Cl. G11C 11/56; G06F 7/58

(52) U.S. Cl. CPC G11C 11/5642; G06F 7/588; G11C 11/5628

(57) ABSTRACT

A ratio of events in a data stream can be probabilistically maintained using a machine which comprises an observation line and circuitry for maintaining the ratio. In such a machine the circuitry may comprise a set of estimator modules, each of which comprises a random number generator and a storage module, wherein the set of estimator modules may comprise a highest order estimator module and a lowest order estimator module.

### BACKGROUND

The ability to create a real time summary of information regarding a data stream as it is being observed has a variety of applications, such as artificial intelligence and system monitoring. However, traditional methods of creating such summaries may be quite complicated, involving features such as circuitry for performing division operations to determine a ratio to characterize the stream. This complexity can be further increased in a case where different events should be treated as having different impacts, such as in tasks where it is desired to retain data in a manner analogous to short term memory, or where it is desired to be able to act quickly to recent events rather than having to wait for sufficient data to be gathered to change a data stream's overall historical ratio. Accordingly, there is a need for technology which can create real time summaries of data streams without requiring circuitry such as dividers, and in particular there is a need for such technology which would also allow for different events to have different levels of impact.

### SUMMARY

Disclosed herein is technology which can provide simplified tracking of ratios in data streams and differential treatment of events through fixed maximum length probabilistic storage elements. This may be performed using a machine which comprises an observation line and circuitry for maintaining the ratio. In such a machine the circuitry may comprise a set of estimator modules, each of which comprises a random number generator and a storage module, wherein the set of estimator modules may comprise a highest order estimator module and a lowest order estimator module. Corresponding methods and systems could also be implemented based on the disclosure set forth herein.

While multiple examples are described, still other examples of the described subject matter will become apparent to those skilled in the art from the following detailed description and drawings, which show and describe illustrative examples of disclosed subject matter. As will be realized, the disclosed subject matter is capable of modifications in various aspects, all without departing from the spirit and scope of the described subject matter. Accordingly, the drawings and detailed description are to be regarded as illustrative in nature and not restrictive.

### BRIEF DESCRIPTION OF THE DRAWINGS

The accompanying drawings, which are incorporated in and constitute a part of this specification, illustrate embodiments of the invention, and, together with the general description of the invention given above, and the detailed description of the embodiments given below, serve to explain the principles of the present invention.

FIG. 1 illustrates an exemplary implementation for a probabilistic storage element, referred to herein as an estimator, with a fixed maximum capacity;

FIG. 2 illustrates a process which a high order estimator module, referred to as a head estimator module, may perform when an observation input signal is provided on an observation line;

FIG. 3 illustrates a process which estimator modules other than the tail module may perform so that, collectively, the estimator may determine whether the denominator of a data stream's ratio should be updated and also automatically update that denominator with any inactive modules which may be present;

FIG. 4 illustrates a mismatch finding process as it could be performed by a tail module of an estimator such as shown in FIG. 1;

FIG. 5 illustrates a process which could be performed by a tail module in an estimator such as shown in FIG. 1 to determine whether one or more values stored in already active modules should be updated;

FIG. 6 illustrates a process which modules of an estimator shown in FIG. 1 other than the head module may perform to update previously stored values in response to an input which had been provided on the observation line;

FIG. 7 illustrates a process a head module in an estimator such as shown in FIG. 1 could update a previously stored value;

FIG. 8 depicts a zoomed in image of a head module such as could be included in an estimator as shown in FIG. 1;

FIG. 9 is a zoomed in image of an intermediate estimator module such as could be included in an estimator as shown in FIG. 1;

FIG. 10 is a zoomed in image of a tail module such as could be included in an estimator as shown in FIG. 1;

FIG. 11 illustrates a potential application of the disclosed technology utilizing a computer and an estimator; and

FIG. 12 illustrates a potential implementation of an estimator with a fixed maximum capacity.

The drawings are not intended to be limiting in any way, and it is contemplated that various embodiments of the invention may be carried out in a variety of other ways, including those not necessarily depicted in the drawings. The accompanying drawings incorporated in and forming a part of the specification illustrate several aspects of the present invention, and together with the description serve to explain the principles of the invention; it being understood, however, that this invention is not limited to the precise arrangements shown.

### DETAILED DESCRIPTION

The following description should not be used to limit the scope of protection provided by this document or any related document. Other examples, features, aspects, embodiments, and advantages of the disclosed technology will become apparent to those skilled in the art from the following description. As will be realized, the disclosed technology is capable of other different and obvious aspects, all without departing from the invention. Accordingly, the drawings and descriptions should be regarded as illustrative in nature and not restrictive.

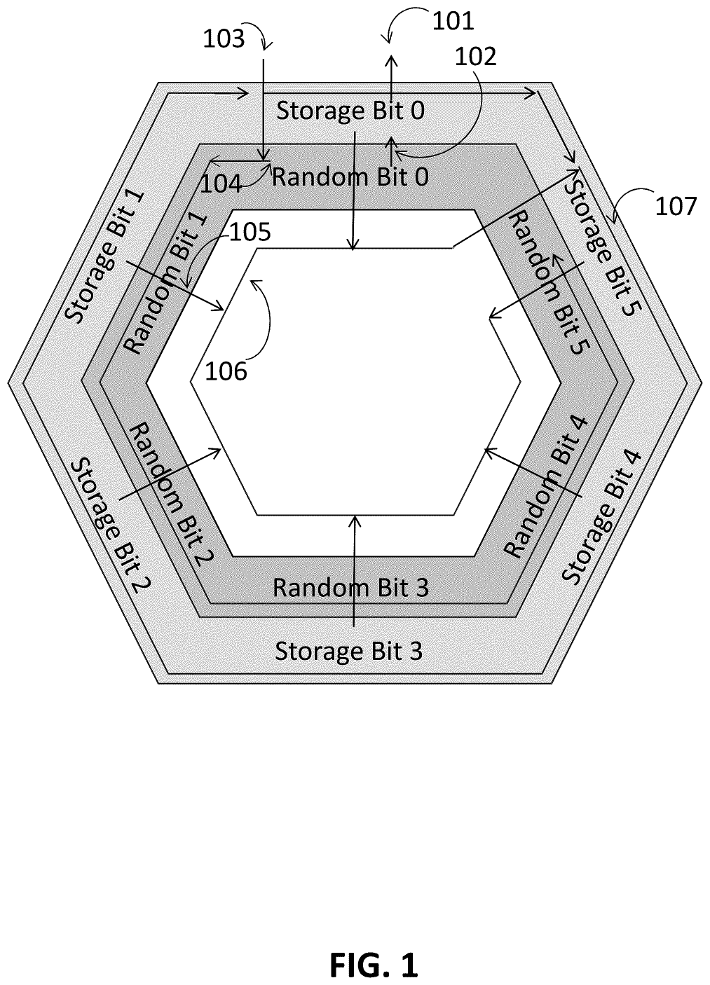

Turning now to FIG. 1, that figure illustrates an exemplary implementation for a probabilistic storage element, referred to herein as an estimator, with a fixed maximum capacity. In such an implementation, a user could provide observations of events from a data stream to the estimator on an observation line 103, so that the estimator could generate a characteristic ratio for the information from that stream. Preferably, these event observations would be provided to the estimator in trinary form, such as by applying a voltage to the observation line 103 in which a positive voltage was represented a positive observation, a negative voltage represented a negative (or non-positive) observation, and zero voltage represented no observation. For instance, a system receiving binary inputs as a data stream could be configured to provide a positive voltage to the observation line 103 on a rising clock edge if it had received a “1” input since the preceding rising edge, to provide negative voltage if it had received a “0” input since the preceding rising edge, and to set the voltage on the observation input line to 0 if no input had been received. The estimator may then use these voltages (or other inputs, in implementations which use characteristics other than voltages to represent data) to automatically generate a characteristic ratio for the data stream which could be provided for a user when he or she sampled the estimator on its line out 101. This ratio may be represented as simply the value stored in the first storage element (e.g., storage bit 0), may be a random number provided along random choice line 102 in the event that no observations from the data stream had yet been made, or could be the string of values stored by the estimator based on observations of the relevant data stream (e.g., the string of consecutive nonzero values, in the tri-state implementation described above).

As shown in FIG. 1, an estimator may be organized into a plurality of storage bit-random bit pairs, referred to herein as modules, which may be connected by a set of three data lines, illustrated in FIG. 1 as an inner loop 106, a middle loop 104, and an outer loop 107. In some embodiments, each estimator module may initially store data indicating that it was not storing data relevant to the data stream being processed. For instance, in the example of a voltage based estimator which would receive trinary inputs from the preceding paragraph, all storage bits in an estimator may initially be set to zero voltage, indicating that they did not include data which had been modified based on observations of the data stream. When an observation was provided on the observation line 103, that observation could initially be used to set the value of the storage bit of the first module. If the first module already had a value in its storage bit (e.g., if storage bit 0 already stored either a positive or negative value in the exemplary three state implementation from the preceding paragraph) the estimator modules may use their previously stored information to probabilistically determine both if the new observation should be stored in a module which did not yet have a value (or, to be more precise, to be stored in a module which did not have a value set based on data from the observation line 103) and if the new observation should be used to update values which were already stored. These determinations may be made via separate probabilistic processes for determining whether an observation input value may be stored in a then inactive (i.e., a module not storing a value set based on data from the data stream) module, and for determining whether an observation input value should be used to update data in already active (i.e., modules storing values set based on data from the data stream) modules. Examples of how those processes may be implemented are described below.

For determining whether an observation input value may be stored in a then inactive module (essentially, determining whether to increase the denominator of a ratio for the data stream) the observation input value may be communicated from module to module via the middle loop 104. When a module which receives the observation input value in this manner was already active, it could not switch itself from inactive to active, but could determine whether a subsequent module which was inactive might be switched. This could be done by, for example, using a comparison between the active module's stored and random values on a comparison line 105 and only passing the observation input to the next module if the random and stored values matched. Then, when (and if) the observation input value finally reached an inactive module via the middle loop 104, it could automatically be used to update the value of the inactive module's storage element, thereby increasing the number of active estimator modules. In this type of approach, the number of active estimator modules could be treated as encoding the denominator (e.g., the denominator may be defined as the two raised to the number of active modules) in a ratio for the data stream, thereby allowing that denominator to be determined without requiring additional circuitry for calculating division, determining probabilities, or even explicitly storing the number of observations at all, thereby allowing an estimator such as shown in FIG. 1 to significantly reduce the complexity of the systems in which it was used.

For determining whether an observation input value should be used to update data already stored in active modules (essentially, determining whether to change the numerator of a ratio for the data stream), the observation input value may be provided to the lowest order module (corresponding to storage bit 5 and random bit 5 in the diagram of FIG. 1, and referred to herein as the tail module) on the outer loop 107. The tail module may also be provided with a random value on the inner loop 106 and, if those values matched, an adjustment process may be performed in which the lowest order active module (which may or may not be the tail module) would update its stored value based on the outer loop (e.g., flipping the value from positive to negative or negative to positive, in the exemplary three state implementation described above). Any carryover could then be forwarded to the next module (e.g., from the module corresponding to storage bit 5 to the module corresponding to storage bit 4) along the outer loop 107 until no further adjustment was needed (e.g., until the modified storage value was equal to the value on the outer loop, in the previously mentioned tri-state implementation). In this way, and particularly in the case of a tri-state implementation in which observation values would only take on either a positive or a negative value, the numerator portion of a ratio for a data stream can be maintained through simplified circuitry at each estimator module.

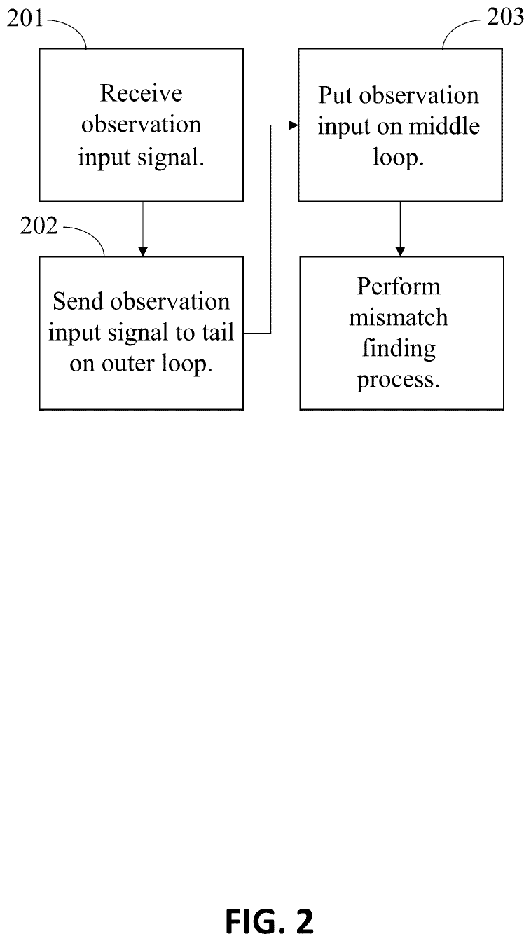

To further illustrate how the modules of an estimator such as shown in FIG. 1 could operate to probabilistically maintain and update a ratio for a data stream, FIGS. 2-7 Illustrate logic which may be performed at each of the modules in an exemplary tri-state implementation such as described above. Turning first to FIG. 2, that figure illustrates a process which a high order estimator module, referred to as a head estimator module, may perform when an observation input signal is provided on an observation line 103. As shown in FIG. 2, once the observation input signal has been received 201, it may be sent 202 to the tail module along the outer loop 107. The observation input value may also be put 203 onto the middle 104, thereby setting the stage for processes through which the numerator and denominator of a ratio for the data stream may be updated.

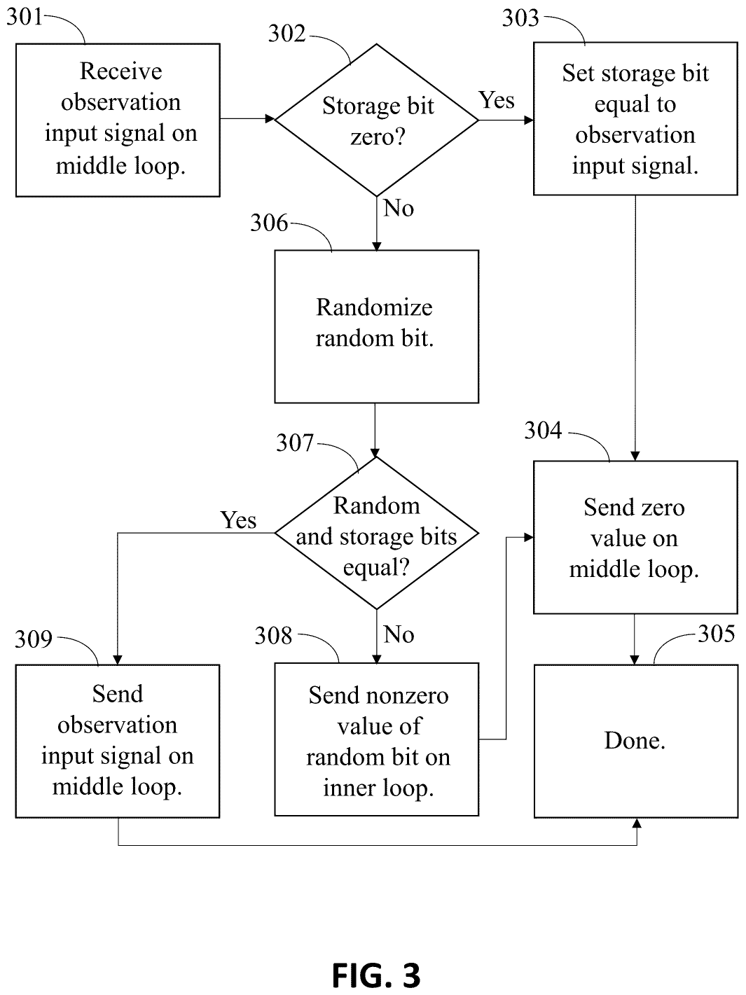

Turning next to FIG. 3, that figure illustrates a process which estimator modules other than the tail module may perform so that, collectively, the estimator may determine whether the denominator of a data stream's ratio should be updated and also automatically update that denominator with any inactive modules which may be present (referred to in FIG. 2 as a “mismatch finding process”). As shown in FIG. 3, this process can be triggered by receiving 301 the observation input signal on the middle loop 104. A check 302 could then be made of whether the module where the process was being performed was an active module. As shown in FIG. 3, in an implementation with three-state storage bits such as described above, this check 302 may be done by checking if the module's storage bit is set at its neutral value (e.g., zero). If the check 302 indicated that the module was inactive, then its storage bit may be set 303 equal to the observation input signal on the middle loop 104, thereby extending the denominator of the data stream's characteristic ratio. Then, because the denominator had been extended, the middle loop value could be set 304 to zero (i.e., the value used in this example to indicate there was not an input observation to be used in updating the denominator), and the process could be done 305 for that module. Alternatively, if the check 302 indicated that the module was active, then a different set of processes may be performed, an example of which is shown in FIG. 3 and described below.

When the process of FIG. 3 is performed by an active module, receipt 301 of the observation input signal on the middle loop 104 could trigger randomization 306 of the module's random bit. This randomization 306 allows the determination of whether to extend the denominator to be probabilistic, as whether the process of FIG. 3 should be performed by the estimator's next module would be determined by a check 307 of whether the random bit was equal to the storage bit of the estimator module. If they were not equal (i.e., if a mismatch is found), this may be treated as indicating that the denominator should not be extended. Accordingly, the value of the middle loop may be set 304 to zero for the estimator's lower order modules. Additionally, the random value may be sent 308 to the tail estimator module on the inner loop 106, so that that module can determine whether to adjust the already stored values, and the mismatch finding process may then be treated as done 305. Alternatively, if the check 307 of the random and storage bits indicated that they were equal, the observation input signal could be sent 309 to the next module on the middle loop 104, and the mismatch finding process could be treated as done 305 for that module, though not for the estimator as a whole.

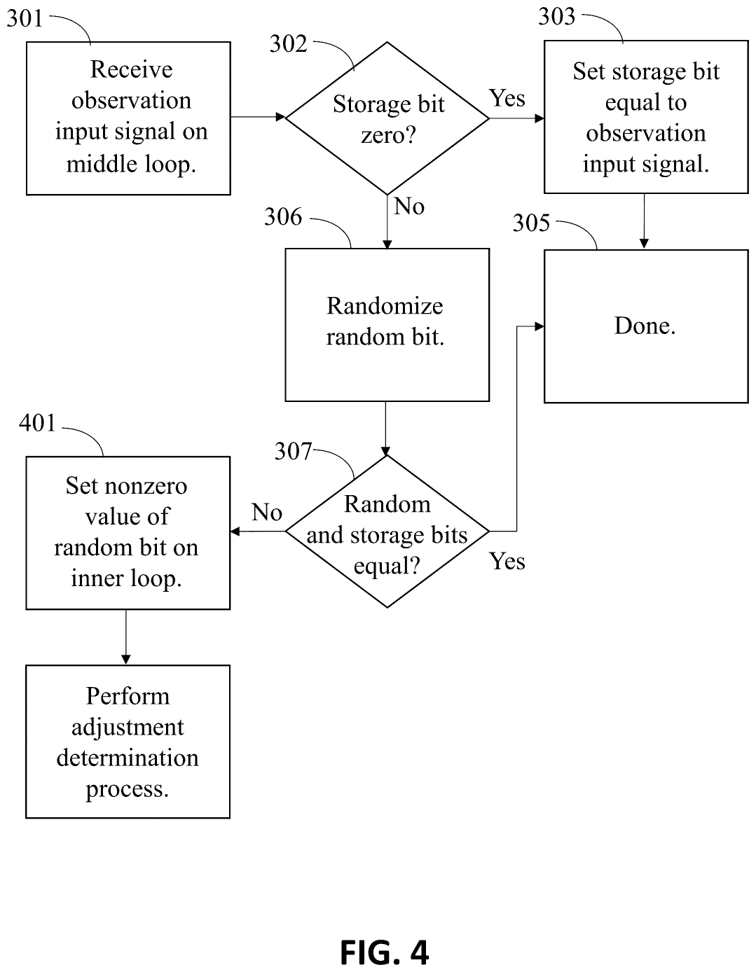

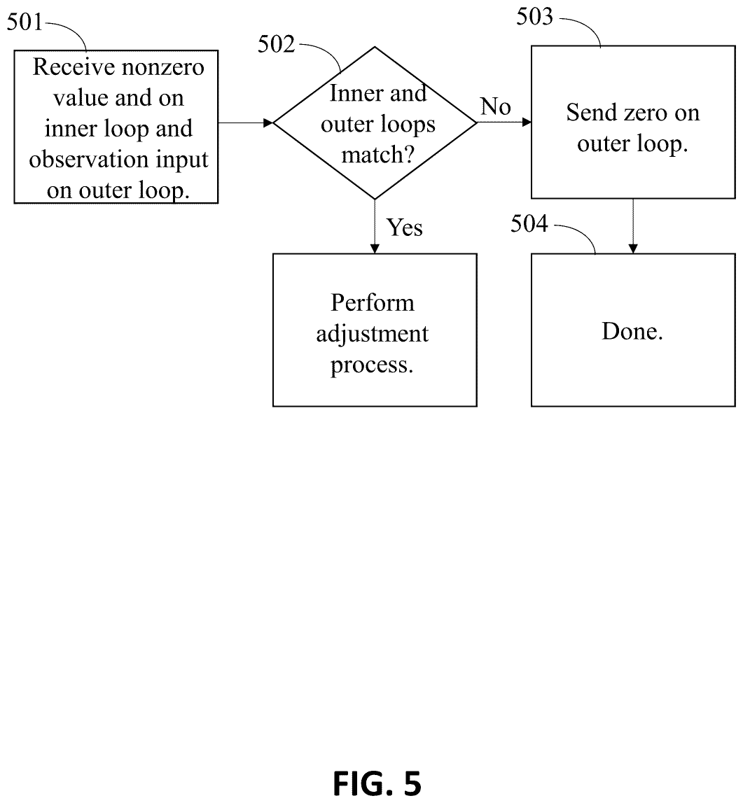

Turning next to FIG. 4, that figure illustrates the mismatch finding process as it could be performed by the tail module, for instance, if a zero value had not been sent 304 on the middle loop 104 by any of the preceding modules. As shown in that figure, the process as performed in a tail module may be largely the same as the process described in the context of FIG. 3. However, the tail module would not need to send either zero or nonzero values to subsequent modules on the middle loop 104, as, in an implementation such as shown in FIG. 1, there would not be any subsequent modules to receive those values. Similarly, when the tail module was active and found that its random and storage bits to be equal, rather than sending 308 the nonzero value of the random bit to the tail module as described above in the context of FIG. 3, it would set 401 its own value on the inner loop as equal to the value of its random bit. Thereafter, it could determine whether one or more of the active modules' values should be and those determinations could be made, processes described below in the context of FIGS. 5-7.

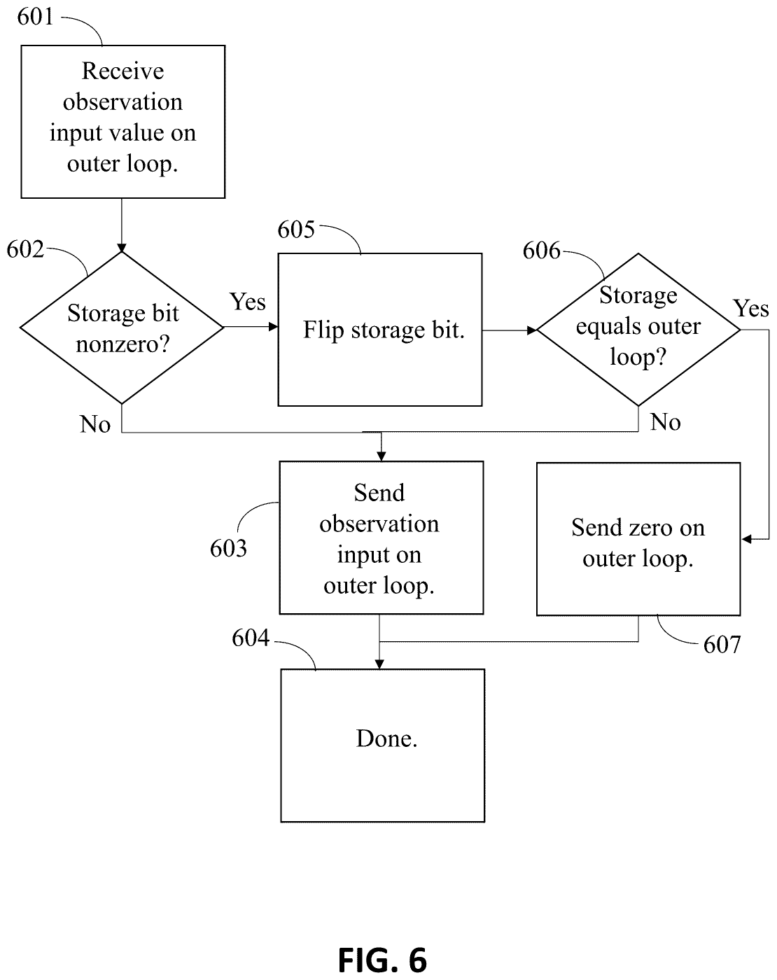

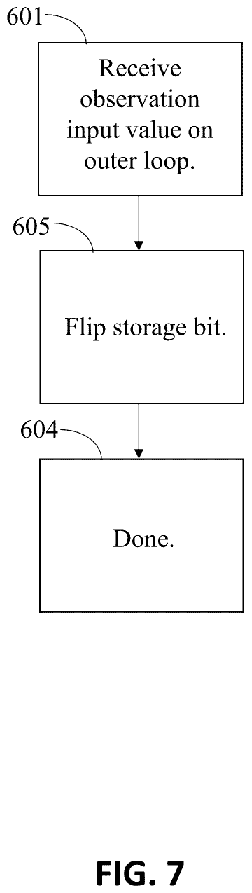

Turning next to FIG. 5, that figure illustrates a process which could be performed by a tail module to determine whether one or more values stored in already active modules should be updated. As shown in FIG. 5, this determination may be triggered by the receipt 501 of nonzero values on both the inner and outer loops of an implementation such as shown in FIG. 1. This may be triggered by the head module sending 202 the observation input signal to the tail module on the outer loop 107 as described in the context of FIG. 2, combined with the value of the inner loop 106 at the tail module being made equal to a random value through the random value either being sent 308 to the tail module as described in the context of FIG. 3, or set 401 to the nonzero random value by the tail module itself as described in the context of FIG. 4. Once nonzero values had been received 501 on both the inner and outer loops, a check 502 could be made as to whether those values matched each other. If they did not, then a zero value could be sent 503 to the next higher order module along the outer loop 107, thereby indicating to that module (and other higher order modules) that no change would need to be made to their stored values, and the adjustment determination would be done 504. Otherwise, if the values on the inner and outer loops did match, then the process of actually adjusting one or more previously stored values could begin and be performed as described below in the context of FIGS. 6 and 7.

Turning next to FIG. 6, that figure illustrates a process which an estimator's modules other than the head module may perform to update previously stored values in response to an input which had been provided on the observation line 103. As shown in FIG. 6, this process may be triggered by a module receiving 601 an observation input value (e.g., any nonzero value) on the outer loop 107. Once the adjustment process was triggered, a check 602 may be performed of whether the module performing the process was inactive (e.g., whether its stored value was zero, in the tri-state implementation described above). If the module was inactive, then it could send 603 the observation input value to the next higher order module on the outer loop 107, and the process could then be treated as done 604 for that module. Alternatively, if the module was active, then its stored value could be updated based on observation input value received 601 on the outer loop 107 (e.g., flipped 605 from negative to positive or positive to negative, in the exemplary tri-state implementation). Once the value had been updated, a check 606 could be made of whether the storage value equaled the value on the outer loop 107. If the values were equal, then this could be treated as indicating that no further carryover from other active modules was necessary, and so a zero value could be sent 607 to the next module on the outer loop 107, and the process could be treated as done 604. A similar process may also be performed in the head module though, as shown in FIG. 7, the adjustment process performed in the head module would be simpler than that shown in FIG. 6, as the head module would not have any higher order modules to consider for carrying over, and so would not need to consider changing the observation value on the outer loop 107.

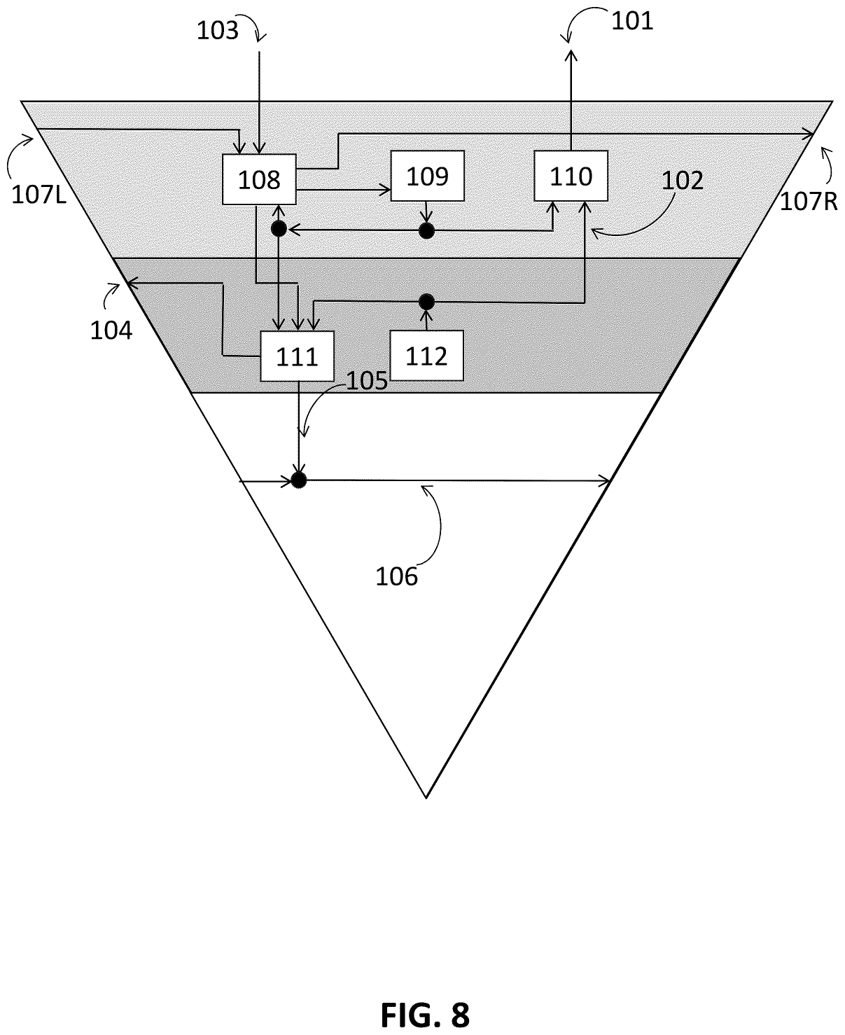

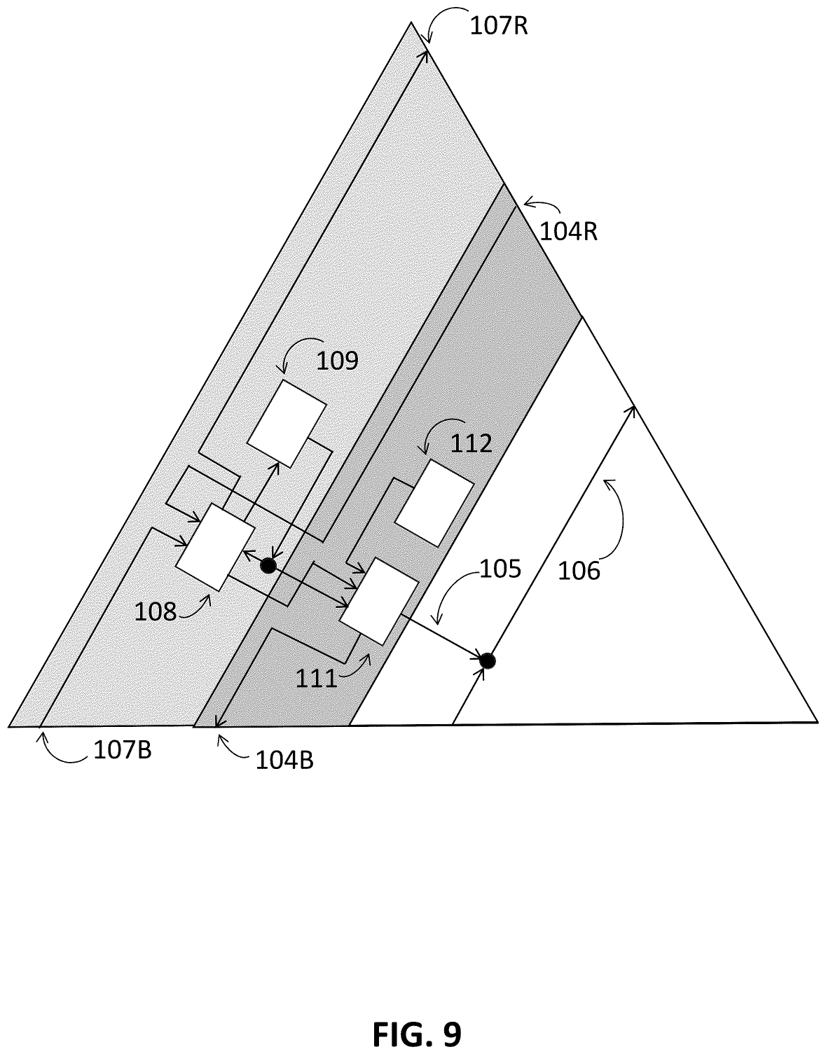

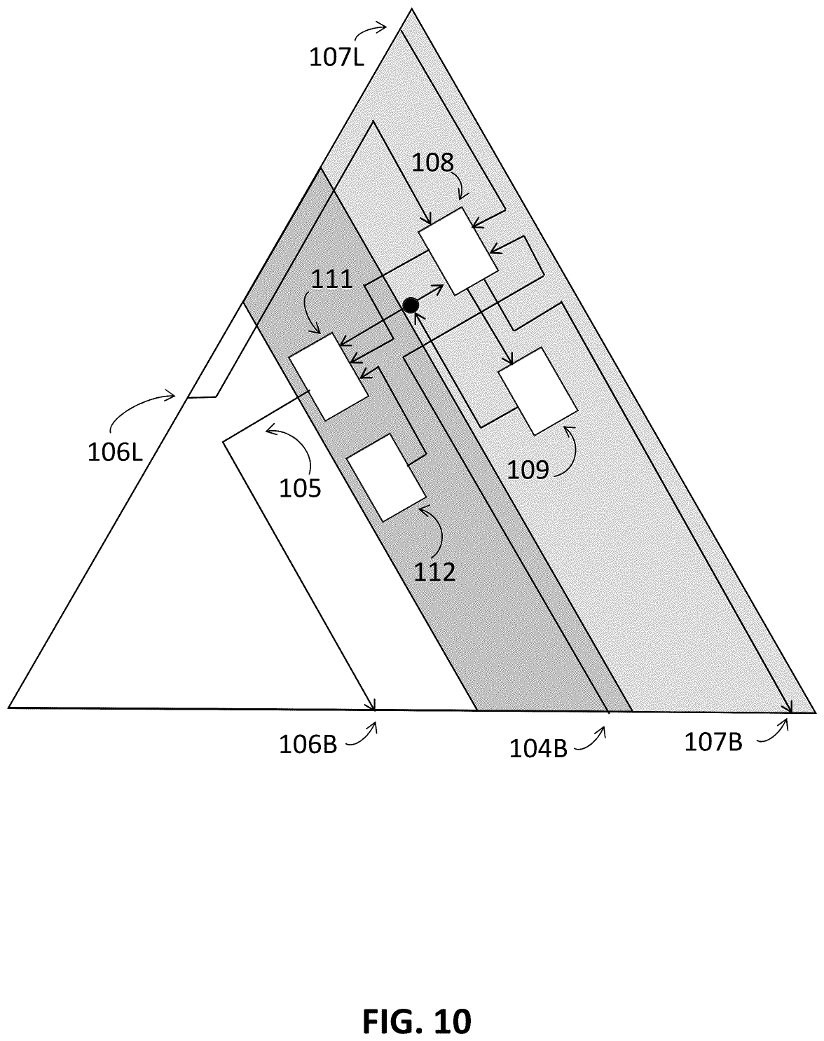

To further illustrate how the disclosed technology may be implemented in practice, FIGS. 8-10 provide more detailed illustrations of how estimator modules in an estimator such as shown in FIG. 1 may be implemented. In particular, FIG. 8 depicts a zoomed image of the head, which is the upper triangle of the hexagon shown in FIG. 1, providing greater detail. FIG. 9 is a zoomed image of an intermediate estimator module, which can represent Estimator Module number 1, 2, 3, or 4, and their corresponding pairings of Storage Bits and Random Bits. The way FIG. 9 is positioned, it represents Module #1. FIG. 10 is a zoomed image of the tail, the upper right of the estimator shown in FIG. 1. Each of those figures, as well as how the components of those figures may be used to provide functionality for an estimator, are discussed in detail below.

Turning first to FIG. 8, in a tri-state estimator such as described above, the storage bit 109 may contain a value that is either positive, zero, or negative. In its initial state, it may contain a zero value. An external device may generate a prediction from the Estimator by sampling Line Out 101. Selector 110 may pass to Line Out 101 the value of the Storage Bit 109 if Storage Bit 109 is non-zero, and may pass the value of the Random Bit 112, if the Storage Bit 109 is zero. Random Choice Line 102 may pass the value of Random Bit 112 to the Selector 110 to support this type of response on the Line Out 101. It should be noted that, in FIG. 8, the outer loop 107 shown in FIG. 1 is illustrated as 107L (Outer Loop 107 entering from the Left side, from an intermediate Estimator Module) and 107R (Outer Loop 107 leaving the Right side, going to the tail Estimator Module).

Determiner 108 may receive inputs from multiple sources: the Observation Line 103, the Storage Bit 109, and the Outer Loop 107L. At the time of the first observation, the value of the Storage Bit 109 may be zero, at which time, the Determiner 108 may pass the value of the Observed Line 103 to the Storage Bit 109, and the Storage Bit 109 may store this new value. In this case, no signal is passed from Determiner 108 to Middle Loop 104. In the event that the Storage Bit 109 is non-zero (which may be the case any time after the first observation has been stored in it), then Determiner 108 may pass the value of Observation Line 103 through to Outer Loop 107R and to Match Checker 111. Match Checker 111 may receive inputs from Determiner 108 (which may be the signal received on Observation Line 103), as well as the Storage Bit 109 and the Random Bit 112. Match Checker 111 compares the Storage Bit 109 with the Random Bit 112. If they are equal, then the input from Determiner 108 is passed to Middle Loop 104. If they are not equal and Storage Bit 109 is non-zero, then Random Bit 112 may be passed to Comparison Line 105 and ultimately to Inner Loop 106. If Storage Bit 109 is zero, then Match Checker 111 may not pass a signal to Middle Loop 104 nor Comparison Line 105.

When Match Checker 111 finds a match between Storage Bit 109 and Random Bit 112 (that is, they are equal), the input from Determiner 108 may be passed to Middle Loop 104, and can be seen on FIG. 9, entering the Intermediate Estimator Module at Middle Loop 104R. Note that FIG. 9, depicts the Middle Loop as 104R (entering from the Right side) and 104B (exiting the Bottom). A similar naming convention is used for Outer Loop 107, utilizing 107R and 107B. The signal passed along Middle Loop 104R may be the same value as the observed signal. It may arrive at Determiner 108 of the Intermediate Module, where a determination may be made as to whether it needs to be immediately stored in Storage Bit 109 because Storage Bit 109 has a zero value. Or it may be passed through Determiner 108 and arrive at Match Checker 111 of the Intermediate Module, which will also have inputs from Storage Bit 109 and Random Bit 112 of the Intermediate Module. Match Checker 111 follows similar logic as it did in the Head Estimator Module shown on FIG. 8, passing either the input from Determiner 108 to Middle Loop 104 (104B in this case), or passing Random Bit 112 to Inner Loop 106 via Comparison Line 105, or not passing any signal whatsoever.

Consider what may happen when one module's Match Checker 111 does not find a match (that is, Storage Bit 109 is non-zero and not equal to Random Bit 112). The value of Random Bit 112 may be passed to Inner Loop 106 via Comparison Line 105. The value of the Random Bit 112 then travels clockwise around the Estimator, possibly passing through multiple Intermediate Modules, through the Head Module, and eventually to the Tail Module. Refer to FIG. 10. This signal may enter the Tail Estimator Module on Inner Loop 106L. It may then be an input to Determiner 108. The Tail Determiner 108 also has an input from the Outer Loop 107L, which was passed from the Head Module (FIG. 8, Outer Loop 107R). Determiner 108 of the Tail Estimator Module may use these two inputs (from Inner Loop 106L and Outer Loop 107L) to determine whether the Estimator will undertake an adjustment process. If these two values are the same, then the process may be to pass values around the Estimator in a clockwise direction, until it finds the first non-zero Storage Bit 109. This may start at the Tail Estimator Module. Its Determiner 108 may refer to the value of Storage Bit 109. If Storage Bit 109 is zero, then Determiner 108 may pass the common value that came from the two side inputs (that is, the common value from Outer Loop 107L and Inner Loop 106L) out to Outer Loop 107B.

However, if Determiner 108 detects a non-zero value of Storage Bit 109, then Determiner 108 may instruct Storage Bit 109 to invert (switching from positive to negative and vice versa). If the new value of the Storage Bit 109 is now the same as the common side input (in the case of the tail Estimator shown on FIG. 10) or the input from the Outer Loop 107B (in the case of an intermediate Module as shown on FIG. 9), then the adjustment (inversion) process is complete, and no further signal is sent out the Outer Loop 107. Otherwise, the Determiner 108 sends the common input signal (received from Inner Loop 106 or Outer Loop 107) out the Outer Loop 107 in a clockwise direction. Upon completion of all adjustments to the Storage Bits 109, the Observation Line 103 is returned to its zero value, indicating that the system is between observations. All Loop signals (that is, Outer Loop 107, Middle Loop 104, and Inner Loop 106) also return to zero at that point as well. All Random Bits 112 may be regenerated at this time as well, or may be regenerated as needed.

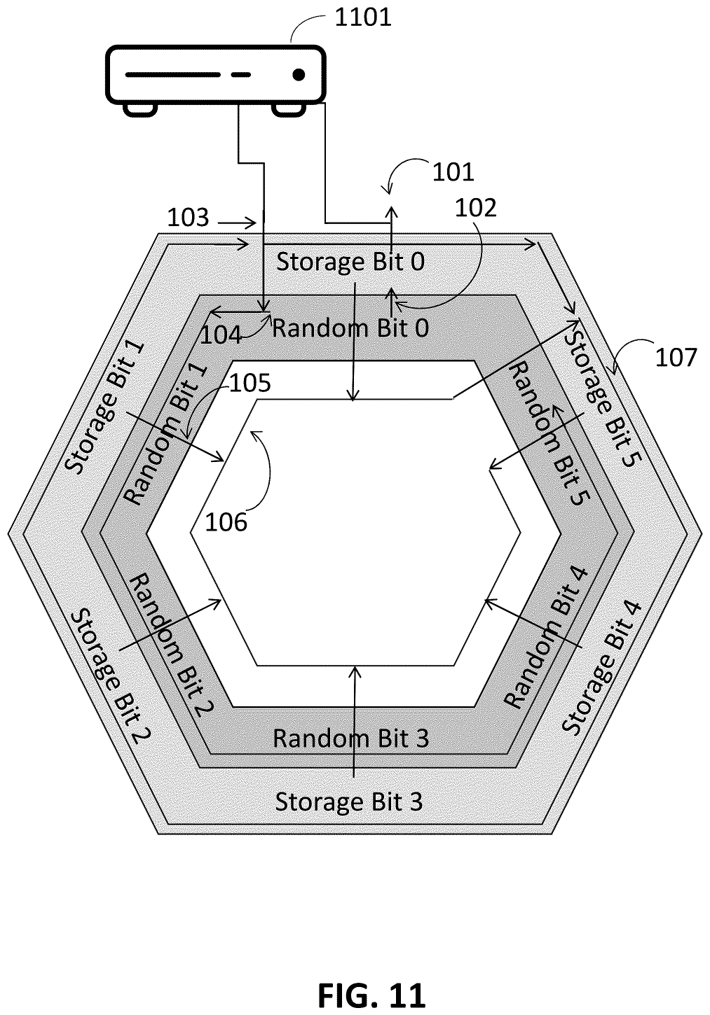

To illustrate how the disclosed technology may be used in practice, consider FIG. 11, which illustrates an application in which computer 1101 could observe events in a data stream and then provide those events to an estimator (e.g., via a system comprising one or more such estimators) such as could be implemented based on this disclosure for analysis. For example, the computer 1101 may be a computer system designed to track failures of various components, that could use estimators such described herein to identify if failures in different components appeared to be correlated (e.g., the ratios of failures for those components might rise or fall together). As another example, the low complexity of fixed length storage elements such as described herein would make them particularly suitable for deployment in cellular automata, where simple hardware components are deployed large numbers of times to support emerging complex behaviors (e.g., the technology described in U.S. patent application Ser. No. 18/113,280, filed on Feb. 23, 2023 for Artificial Intelligence Based on Cellular Automata, the disclosure of which is hereby incorporated by reference in its entirety). Further practical applications are also possible, and will be immediately apparent to those skilled in the art in light of this disclosure. Accordingly, the above examples should be understood as being illustrative only, and should not be treated as limiting.

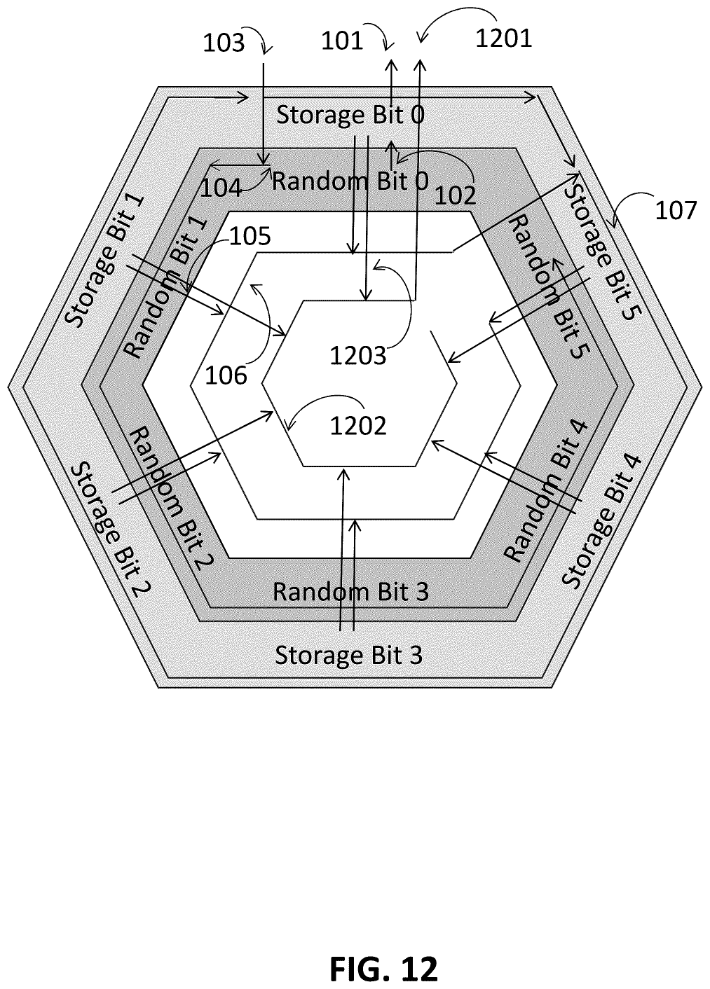

While the above disclosure illustrated how fixed length estimators may be implemented and used in a variety of manners, it should be understood that that disclosure is intended to be illustrative only, and that variations on the particular examples provided above are possible and will be immediately apparent to those of skill in the art in light of this disclosure. To illustrate, consider FIG. 12, which illustrates an implementation of a fixed length estimator such as shown in FIG. 1 that also includes a Simulation Line 1201 which is connected to Fourth Loop 1202. In an implementation following FIG. 12, when checking check 307 whether a module's random and storage bits are equal,, if they are not equal, then the value of the Storage Bit 109 may be passed along Connector 1203 to Fourth Loop 1202. This process may pass the highest order non-zero storage bit that does not match its corresponding random bit to the Simulation Line 1201, which may have the effect of simulating a data stream with the approximate characteristics of the previously observed data stream on Observation Line 103. In the event that every non-zero storage bit matches its corresponding random bit, Simulation Line 1201 may output a zero value (that is, neither positive nor negative), or may output a random value (either positive or negative, chosen randomly), depending on the implementation.

As another illustration of a type of variation on implementations of the disclosed technology, consider the modification of the denominator encoded in the number of active modules in an estimator. In embodiments which implement logic such as shown in FIGS. 3-4, because the denominator is increased by setting 303 the stored value of an inactive estimator module when the denominator is increased (e.g., doubled through adding another bit), the numerator is also increased by approximately the same proportion (e.g., approximately doubled, through adding another bit, though the specific increase in the numerator would depend on the value of the observation input). In some cases, this may be desirable behavior, since it would maintain the ratio for the data stream at approximately the same value despite the fact that that ratio would be encoded using additional active estimator modules. However, in other cases, it may be desirable to hold the numerator of the ratio constant even when the denominator increases, and so in such cases increasing the denominator by adding an additional active module may be accompanied by steps intended to avoid modification to the numerator of a ratio for the data stream (e.g., shifting the values stored in the active estimator modules to avoid the addition of a new active estimator module impacting the numerator). Other variations are also possible, and will be immediately apparent to those of skill in the art in light of this disclosure. Accordingly, the protection provided by this document, or by any related document, should not be treated as being limited by the particular examples and illustrations set forth herein.

To further illustrate potential variations on the ways the disclosed technology could be implemented, the below examples specify various non-exhaustive ways in which the teachings herein may be combined or applied. It should be understood that the following examples, like the other examples and variations set forth herein, are not intended to restrict the coverage of any claims that may be presented at any time in this document or any related document. No disclaimer is intended. The following examples are being provided for nothing more than merely illustrative purposes. It is contemplated that the various teachings herein may be arranged and applied in numerous other ways. It is also contemplated that some variations may omit certain features referred to in the below examples. Therefore, none of the aspects or features referred to below should be deemed critical unless otherwise explicitly indicated as such at a later date by the inventor or by a successor in interest to the inventor. If any claims are presented in this document or a related document that include additional features beyond those referred to below, those additional features shall not be presumed to have been added for any reason relating to patentability.

### Example 1

A machine comprising: a) an observation line; and b) circuitry to probabilistically maintain a ratio for a data stream based on positive and negative observations provided to the estimator on the observation line, wherein the circuitry comprises a set of estimator modules, wherein each estimator module comprises: i) a random number generator; and ii) a storage element; and wherein the set of estimator modules comprises a highest order estimator module and a lowest order estimator module.

### Example 2

The machine of example 1, wherein for each estimator module from the set of estimator modules: a) the storage element comprised by that estimator module is a trinary storage element having a set of potential storage states comprising a first state, a second state, and a third state; b) that estimator module comprises an observation input line having a plurality of potential input statement comprising the first state, the second state and the third state; c) that estimator module comprises an adjustment input line having a plurality of potential adjustment states comprising the first state, the second state and the third state; and d) the random number generator comprised by that estimator module is a binary random number generating adapted to provide randomized values having a set of potential random states comprising the first state and the second state.

### Example 3

The machine of example 2, wherein, for each estimator module from the set of estimator modules, the storage element and observation input line comprised by that estimator module are both adapted to represent the first state as a positive voltage, the second state as a negative voltage, and the third state as zero voltage.

### Example 4

The machine of example 2, wherein: a) the circuitry is configured to encode a denominator for the ratio for the data stream in a number of estimator modules comprising storage elements which are not in the third state; b) the circuitry is configured to probabilistically determine whether to increase the denominator for the ratio for the data stream by, at each estimator module, based on the observation input line of that estimator module not being in the third state: i) in the event that the storage element comprised by that estimator module is in the third state: A) putting the storage element comprised by that estimator module into the same state as the observation input line comprised by that estimator module; and B) putting the observation input line comprised by a lower order neighboring estimator module, if any, into the third state; ii) in the event that the storage element comprised by that estimator is not in the third state: A) obtaining, from the random number generator comprised by that estimator, a random value; B) performing a comparison, wherein performing the comparison comprises comparing the random value with the storage element comprised by that estimator module; and C) selectively, based on the comparison: I) putting the observation input line comprised by the lower order neighboring estimator module, if any, into the state of the observation input line comprised by that estimator module; or II) putting a mismatch identification line comprised by the lowest order estimator module into a state of the random value, and putting the observation input line comprised by the lower order neighboring estimator module, if any, into the third state.

### Example 5

The machine of example 2, wherein: a) the highest order estimator module comprises circuitry to, based on an observation input value being received on the observation line, put the adjustment line comprised by the lowest order estimator module into a state of the observation input value; b) the lowest order estimator module comprises circuitry to based on the adjustment line comprised by that estimator module not being in the third state and on the mismatch identification line comprised by that estimator module not being in the third state: i) perform an adjustment comparison, wherein the adjustment comparison comprises comparing the adjustment line comprised by that estimator module and the mismatch identification line comprised by that estimator module; ii) in the event that the adjustment line and the mismatch identification line comprised by that estimator module do not match, put an adjustment line comprised by a second from lowest order estimator module into the third state; and iii) in the event that the adjustment line and the mismatch identification line comprised by that estimator module match, modify one or more storage elements based on activating adjustment circuitry comprised by that estimator module.

### Example 6

The machine of example 5, wherein: a) each estimator module from the set of estimator modules comprises adjustment circuitry; b) for each estimator module from the set of estimator modules, the adjustment circuitry comprised by that estimator module comprises circuitry to, in the event the adjustment line comprised by that estimator module is not in the third state: i) in the event that the storage element comprised by that estimator module is in the first state, put the storage element comprised by that estimator module into the second state and perform a comparison of the modified storage element state with the adjustment line's state; ii) in the event that the storage element comprised by that estimator module is in the second state, put the storage element comprised by that estimator module into the first state and perform the comparison of the modified storage element state with the adjustment line's state; c) for each estimator module except the highest order estimator module, the adjustment circuitry comprised by that estimator module comprises circuitry to: i) in the event that the storage element comprised by that estimator module is in the third state, put the adjustment line comprised by a neighboring higher order estimator module into a same state as the adjustment line comprised by that estimator module; ii) in the event the comparison of the modified storage element state with the adjustment line's state indicates a match, put the adjustment line comprised by the neighboring higher order estimator module into the third state; and iii) in the event the comparison of the modified storage element state with the adjustment line's state does not indicate a match, put the adjustment line comprised by the neighboring higher order estimator module into the same state as the adjustment line comprised by that estimator module.

### Example 7

The machine of example 1, wherein: a) each estimator module from the set of estimator modules has two neighboring estimator modules; b) the highest order estimator module has a second highest order estimator module as one neighbor, and the lowest order estimator module as its other neighbor; c) the lowest order estimator module has a second lowest order estimator module as one neighbor, and the highest order estimator module as its other neighbor; and d) either estimator module other than the highest order estimator module and the lowest order estimator module has a higher order estimator module as one neighbor, and a lower order estimator module as its other neighbor.

### Example 8

The machine of example 7, wherein the set of estimator modules consists of six estimator modules.

### Example 9

The machine of example 1, wherein the circuitry to probabilistically maintain the ratio for the data stream comprises: a) a first data line forming a first loop around the estimator modules; b) a second data line forming a second loop around the estimator modules; c) a third data line forming a third loop around the estimator modules; and d) circuitry to: i) convey data from the highest order estimator module to the lowest order estimator module and from the lowest order estimator module to progressively higher order estimator modules until reaching the highest order estimator module around the first loop; ii) convey data from the highest order estimator module to the progressively lower order estimator modules until reaching the lowest order estimator module around the second loop; and iii) convey data to the lowest order estimator module from any other estimator module around the third loop.

### Example 10

The machine of example 9, wherein: a) the machine comprises circuitry to generate a simulated data stream emulating the data stream whose ratio the machine comprises circuitry configured to maintain; b) the circuitry to generate the simulated data stream comprises circuitry to, at each estimator module: i) perform an evaluation, wherein the evaluation is of whether a value of the storage element comprised that estimator module matches a value provided by the random number generator comprised by that estimator module; and ii) based on the evaluation, selectively place the value of the storage element comprised by that estimator module onto a fourth data line forming a fourth loop around the estimator modules.

### Example 11

The machine of example 1, wherein the highest order estimator module and the lowest order estimator module are a single estimator module.

### Example 12

A method for probabilistically maintaining a ratio for a data stream based on positive and negative observations of events in that data stream, the method comprising: a) receiving on an observation line of an estimator, an observation input value representing an event from the data stream; b) performing a set of determinations, the set of determinations comprising determining, using a set of estimator modules comprised by the estimator: i) whether to update a denominator of the ratio for the data stream by increasing a length of data encoding the denominator; and ii) whether to update a numerator of the ratio for the data stream by modifying one or more stored values which had been previously been set based on observations of the data stream; wherein the set of estimator modules comprises a highest order estimator module and a lowest order estimator module, and wherein each estimator module comprises a random number generator and a storage element; c) based on the set of determinations: i) updating the denominator of the ratio for the data stream by increasing the length of data encoding the denominator; and ii) updating the numerator of the ratio for the data stream by modifying one or more stored values which had previously been set based on observations of the data stream.

### Example 13

The method of example 12, wherein, for each estimator module from the set of estimator modules: a) the storage element comprised by that estimator module is a trinary storage element having a set of potential storage states comprising a first state, a second state, and a third state; b) that estimator module comprises an observation input line having a plurality of potential input statement comprising the first state, the second state and the third state; c) that estimator module comprises an adjustment input line having a plurality of potential adjustment states comprising the first state, the second state and the third state; and d) the random number generator comprised by that estimator module is a binary random number generating adapted to provide randomized values having a set of potential random states comprising the first state and the second state.

### Example 14

The method of example 13, wherein, for each estimator module from the set of estimator modules, the storage element and observation input line comprised by that estimator module are both adapted to represent the first state as a positive voltage, the second state as a negative voltage, and the third state as zero voltage.

### Example 15

The method of example 13, wherein: a) the data encoding the denominator of the ratio for the data stream is a number of estimator modules comprising storage elements which are not in the third state; b) each estimator module from the set of estimator modules comprises mismatch finding circuitry to, based on the observation input line of that estimator module not being in the third state: i) in the event that the storage element comprised by that estimator module is in the third state: A) putting the storage element comprised by that estimator module into the same state as the observation input line comprised by that estimator module; and B) putting the observation input line comprised by a lower order neighboring estimator module, if any, into the third state; ii) in the event that the storage element comprised by that estimator is not in the third state: A) obtaining, from the random number generator comprised by that estimator, a random value; B) performing a comparison, wherein performing the comparison comprises comparing the random value with the storage element comprised by that estimator module; and C) selectively, based on the comparison: I) putting the observation input line comprised by the lower order neighboring estimator module, if any, into the state of the observation input line comprised by that estimator module; or II) putting a mismatch identification line comprised by the lowest order estimator module into a state of the random value, and putting the observation input line comprised by the lower order neighboring estimator module, if any, into the third state; c) determining whether to update the denominator of the ratio for the data stream and updating the denominator of the ratio for the data stream are performed by activating the mismatch finding circuitry of one or more estimator modules, starting with the highest order estimator modules and proceeding through progressively lower order estimator modules until satisfaction of at least on condition from a group consisting of: i) mismatch finding circuitry comprised by an estimator module having a storage element in the third state is activated; ii) the mismatch finding circuitry comprised by the lowest order estimator module is activated; and iii) the mismatch identification line comprised by the lowest order estimator module is put into a state other than the third state.

### Example 16

The method of example 13, wherein: a) the method comprises the highest order estimator module, based on receiving an observation input value on the observation line, putting the adjustment line comprised by the lowest order estimator module into a state of the observation input value; b) determining whether to update the numerator of the ratio for the data stream by modifying one or more stored values which had been previously been set based on observations of the data stream comprises the lowest order estimator module, based on the adjustment line comprised by that estimator module not being in the third state and on the mismatch identification line comprised by that estimator module not being in the third state: i) performing an adjustment comparison, wherein the adjustment comparison comprises comparing the adjustment line comprised by that estimator module and the mismatch identification line comprised by that estimator module; ii) based on the adjustment comparison, selectively performing an act from: A) putting an adjustment line comprised by a second from lowest order estimator module into the third state; and B) activating adjustment circuitry comprised by that estimator module.

### Example 17

The method of claim 16, wherein: a) each estimator module from the set of estimator modules comprises adjustment circuitry; b) for each estimator module from the set of estimator modules, the adjustment circuitry comprised by that estimator module comprises circuitry to, in the event the adjustment line comprised by that estimator module is not in the third state: i) in the event that the storage element comprised by that estimator module is in the first state, put the storage element comprised by that estimator module into the second state and perform a comparison of the modified storage element state with the adjustment line's state; ii) in the event that the storage element comprised by that estimator module is in the second state, put the storage element comprised by that estimator module into the first state and perform the comparison of the modified storage element state with the adjustment line's state; c) for each estimator module except the highest order estimator module, the adjustment circuitry comprised by that estimator module comprises circuitry to: i) in the event that the storage element comprised by that estimator module is in the third state, put the adjustment line comprised by a neighboring higher order estimator module into a same state as the adjustment line comprised by that estimator module; ii) in the event the comparison of the modified storage element state with the adjustment line's state indicates a match, put the adjustment line comprised by the neighboring higher order estimator module into the third state; and iii) in the event the comparison of the modified storage element state with the adjustment line's state does not indicate a match, put the adjustment line comprised by the neighboring higher order estimator module into the same state as the adjustment line comprised by that estimator module; and d) updating the numerator of the ratio for the data stream by modifying one or more stored values which had previously been set based on observations of the data stream comprises activating the adjustment circuitry of the lowest order estimator module.

### Example 18

The method of example 12, wherein: a) each estimator module from the set of estimator modules has two neighboring estimator modules; b) the highest order estimator module has a second highest order estimator module as one neighbor, and the lowest order estimator module as its other neighbor; c) the lowest order estimator module has a second lowest order estimator module as one neighbor, and the highest order estimator module as its other neighbor; and d) either estimator module other than the highest order estimator module and the lowest order estimator module has a higher order estimator module as one neighbor, and a lower order estimator module as its other neighbor.

### Example 19

The method of example 18, wherein the set of estimator modules consists of six estimator modules.

### Example 20

The method of example 12, wherein: a) updating the numerator of the ratio for the data stream by modifying one or more stored values which had previously been set based on observations of the data stream comprises: conveying data from the lowest order estimator module to progressively higher order estimator modules via a first data line forming a first loop around the estimator modules; and b) determining whether to update the denominator of the ratio for the data stream and updating the denominator of the ratio for the data stream comprise: i) conveying data from the highest order estimator module to progressively lower order estimator modules until reaching the lowest order estimator module via a second data line forming a second loop around the estimator modules; and ii) conveying data from an estimator module other than the highest order estimator module to the lowest order estimator module via third data line forming a third loop around the estimator modules.

### Example 21

The method of example 12, further comprising generating a simulated data stream emulating the data stream based on, at each estimator module from the set of estimator modules: a) performing an evaluation, wherein the evaluation is of whether a value of the storage element comprised that estimator module matches a value provided by the random number generator comprised by that estimator module; and b) based on the evaluation, selectively place the value of the storage element comprised by that estimator module onto a data line forming a loop around the estimator modules.

### Example 22

The method of example 12, wherein the highest order estimator module and the lowest order estimator module are a single estimator module.

### Example 23

A system comprising: a) a computer configured to take observations of events in a data stream; and b) means for probabilistically maintaining a ratio for the data stream based on event inputs from the computer.

It should be understood that any one or more of the teachings, expressions, embodiments, examples, etc. described herein may be combined with any one or more of the other teachings, expressions, embodiments, examples, etc. that are described herein. The above-described teachings, expressions, embodiments, examples, etc. should therefore not be viewed in isolation relative to each other. Various suitable ways in which the teachings herein may be combined will be readily apparent to those of ordinary skill in the art in view of the teachings herein. Such modifications and variations are intended to be included within the scope of the claims. Other variations are also possible, and will be immediately apparent to and could be implemented without undue experimentation by those of ordinary skill in the art in light of this disclosure. Accordingly, the protection provided by this document, or any related document, should not be treated as being limited to the embodiments, examples and variations described herein, but instead should be understood as being defined by the claims set forth in the relevant document when the terms of those claims which are explicitly defined in the following paragraphs or by subsequently provided explicit definitions are given their explicit definitions, and when the other terms are given their broadest reasonable definitions as provided by a general purpose dictionary.

In this document, “based on” should be understood to mean that something is determined at least in part by the thing it is indicated as being “based on.” The phrase “based EXCLUSIVELY on” is used to indicate that something must be completely determined based on something else.

In this document, modifiers such as “first,” “second,” etc. should be understood as labels used to facilitate identification of a particular item being referred to, and, unless context clearly indicates otherwise, should not be understood as implying any required order or other relationship between the labeled objects. For example, a statement that there is a “first value” and a “second value” should not be understood as implying that one of the values comes first, or is determined first, or even that the “first value” and the “second value” are necessarily different values. Similarly a reference to a cell as a “processing cell,” a “memory cell” or a “connection cell” should not be treated as implying structural or functional requirements for such cell, but instead should be understood as a use of the

In this document, “means for probabilistically maintaining a ratio for the data stream based on event inputs from the computer” should be understood as a means plus function limitation as provided for in 35 U.S.C. § 112(f), which the function is “maintaining a ratio for the data stream” and the corresponding structure is an estimator such as illustrated in FIG. 1 comprising estimator modules such as shown in FIGS. 8, 9 and 10.

In this document, “set” should be understood to refer to a number, group or combination of zero or more elements of similar nature, design or function. The terms “subset” and “superset” should be understood as being synonymous with set, with the different terms being used for the sake of understanding, and with a subset and a superset of a set potentially each having the same cardinality as the set, rather than necessarily being smaller or larger than the set they are contained by (in the case of a subset) or that they contain (in the case of a superset).

In this document, “simultaneously” and “simultaneous” should be understood to mean received during a single measured unit of time. For example, in a system in which signals are received and stored for a fixed period (e.g., five milliseconds) before being discarded, then two signals received within the fixed period (e.g., within a five millisecond period) would be considered to have been received simultaneously.

I claim:

1. A machine comprising:
a) an observation line; and
b) circuitry to probabilistically maintain a ratio for a data stream based on positive and negative observations provided to the estimator on the observation line, wherein the circuitry comprises a set of estimator modules, wherein each estimator module comprises:
i) a random number generator; and
ii) a storage element;
and wherein the set of estimator modules comprises a highest order estimator module and a lowest order estimator module.

2. The machine of claim 1, wherein for each estimator module from the set of estimator modules:
a) the storage element comprised by that estimator module is a trinary storage element having a set of potential storage states comprising a first state, a second state, and a third state;
b) that estimator module comprises an observation input line having a plurality of potential input statement comprising the first state, the second state and the third state;
c) that estimator module comprises an adjustment input line having a plurality of potential adjustment states comprising the first state, the second state and the third state; and
d) the random number generator comprised by that estimator module is a binary random number generating adapted to provide randomized values having a set of potential random states comprising the first state and the second state.

3. The machine of claim 2, wherein, for each estimator module from the set of estimator modules, the storage element and observation input line comprised by that estimator module are both adapted to represent the first state as a positive voltage, the second state as a negative voltage, and the third state as zero voltage.

4. The machine of claim 2, wherein:
a) the circuitry is configured to encode a denominator for the ratio for the data stream in a number of estimator modules comprising storage elements which are not in the third state;
b) the circuitry is configured to probabilistically determine whether to increase the denominator for the ratio for the data stream by, at each estimator module, based on the observation input line of that estimator module not being in the third state:
i) in the event that the storage element comprised by that estimator module is in the third state:
A) putting the storage element comprised by that estimator module into the same state as the observation input line comprised by that estimator module; and
B) putting the observation input line comprised by a lower order neighboring estimator module, if any, into the third state;
ii) in the event that the storage element comprised by that estimator is not in the third state:
A) obtaining, from the random number generator comprised by that estimator, a random value;
B) performing a comparison, wherein performing the comparison comprises comparing the random value with the storage element comprised by that estimator module; and
C) selectively, based on the comparison:
I) putting the observation input line comprised by the lower order neighboring estimator module, if any, into the state of the observation input line comprised by that estimator module; or
II) putting a mismatch identification line comprised by the lowest order estimator module into a state of the random value, and putting the observation input line comprised by the lower order neighboring estimator module, if any, into the third state.

5. The machine of claim 2, wherein:
a) the highest order estimator module comprises circuitry to, based on an observation input value being received on the observation line, put the adjustment line comprised by the lowest order estimator module into a state of the observation input value;
b) the lowest order estimator module comprises circuitry to based on the adjustment line comprised by that estimator module not being in the third state and on the mismatch identification line comprised by that estimator module not being in the third state:
i) perform an adjustment comparison, wherein the adjustment comparison comprises comparing the adjustment line comprised by that estimator module and the mismatch identification line comprised by that estimator module;
ii) in the event that the adjustment line and the mismatch identification line comprised by that estimator module do not match, put an adjustment line comprised by a second from lowest order estimator module into the third state; and
iii) in the event that the adjustment line and the mismatch identification line comprised by that estimator module match, modify one or more storage elements based on activating adjustment circuitry comprised by that estimator module.

6. The machine of claim 5, wherein:
a) each estimator module from the set of estimator modules comprises adjustment circuitry;
b) for each estimator module from the set of estimator modules, the adjustment circuitry comprised by that estimator module comprises circuitry to, in the event the adjustment line comprised by that estimator module is not in the third state:
i) in the event that the storage element comprised by that estimator module is in the first state, put the storage element comprised by that estimator module into the second state and perform a comparison of the modified storage element state with the adjustment line's state;
ii) in the event that the storage element comprised by that estimator module is in the second state, put the storage element comprised by that estimator module into the first state and perform the comparison of the modified storage element state with the adjustment line's state;
c) for each estimator module except the highest order estimator module, the adjustment circuitry comprised by that estimator module comprises circuitry to:
i) in the event that the storage element comprised by that estimator module is in the third state, put the adjustment line comprised by a neighboring higher order estimator module into a same state as the adjustment line comprised by that estimator module;
ii) in the event the comparison of the modified storage element state with the adjustment line's state indicates a match, put the adjustment line comprised by the neighboring higher order estimator module into the third state; and
iii) in the event the comparison of the modified storage element state with the adjustment line's state does not indicate a match, put the adjustment line comprised by the neighboring higher order estimator module into the same state as the adjustment line comprised by that estimator module.

7. The machine of claim 1, wherein:
a) each estimator module from the set of estimator modules has two neighboring estimator modules;
b) the highest order estimator module has a second highest order estimator module as one neighbor, and the lowest order estimator module as its other neighbor;
c) the lowest order estimator module has a second lowest order estimator module as one neighbor, and the highest order estimator module as its other neighbor; and
d) either estimator module other than the highest order estimator module and the lowest order estimator module has a higher order estimator module as one neighbor, and a lower order estimator module as its other neighbor.

8. The machine of claim 7, wherein the set of estimator modules consists of six estimator modules.

9. The machine of claim 1, wherein the circuitry to probabilistically maintain the ratio for the data stream comprises:
a) a first data line forming a first loop around the estimator modules;
b) a second data line forming a second loop around the estimator modules;
c) a third data line forming a third loop around the estimator modules; and
d) circuitry to:
i) convey data from the highest order estimator module to the lowest order estimator module and from the lowest order estimator module to progressively higher order estimator modules until reaching the highest order estimator module around the first loop;
ii) convey data from the highest order estimator module to the progressively lower order estimator modules until reaching the lowest order estimator module around the second loop; and
iii) convey data to the lowest order estimator module from any other estimator module around the third loop.

10. The machine of claim 9, wherein:
a) the machine comprises circuitry to generate a simulated data stream emulating the data stream whose ratio the machine comprises circuitry configured to maintain;
b) the circuitry to generate the simulated data stream comprises circuitry to, at each estimator module:
i) perform an evaluation, wherein the evaluation is of whether a value of the storage element comprised that estimator module matches a value provided by the random number generator comprised by that estimator module; and
ii) based on the evaluation, selectively place the value of the storage element comprised by that estimator module onto a fourth data line forming a fourth loop around the estimator modules.

11. The machine of claim 1, wherein the highest order estimator module and the lowest order estimator module are a single estimator module.

12. A method for probabilistically maintaining a ratio for a data stream based on positive and negative observations of events in that data stream, the method comprising:
a) receiving on an observation line of an estimator, an observation input value representing an event from the data stream;
b) performing a set of determinations, the set of determinations comprising determining, using a set of estimator modules comprised by the estimator:
i) whether to update a denominator of the ratio for the data stream by increasing a length of data encoding the denominator; and
ii) whether to update a numerator of the ratio for the data stream by modifying one or more stored values which had been previously been set based on observations of the data stream;
wherein the set of estimator modules comprises a highest order estimator module and a lowest order estimator module, and wherein each estimator module comprises a random number generator and a storage element;
c) based on the set of determinations:
i) updating the denominator of the ratio for the data stream by increasing the length of data encoding the denominator; and
ii) updating the numerator of the ratio for the data stream by modifying one or more stored values which had previously been set based on observations of the data stream.

13. The method of claim 12, wherein, for each estimator module from the set of estimator modules:
a) the storage element comprised by that estimator module is a trinary storage element having a set of potential storage states comprising a first state, a second state, and a third state;
b) that estimator module comprises an observation input line having a plurality of potential input statement comprising the first state, the second state and the third state;
c) that estimator module comprises an adjustment input line having a plurality of potential adjustment states comprising the first state, the second state and the third state; and
d) the random number generator comprised by that estimator module is a binary random number generating adapted to provide randomized values having a set of potential random states comprising the first state and the second state.

14. The method of claim 13, wherein, for each estimator module from the set of estimator modules, the storage element and observation input line comprised by that estimator module are both adapted to represent the first state as a positive voltage, the second state as a negative voltage, and the third state as zero voltage.

15. The method of claim 13, wherein:
a) the data encoding the denominator of the ratio for the data stream is a number of estimator modules comprising storage elements which are not in the third state;
b) each estimator module from the set of estimator modules comprises mismatch finding circuitry to, based on the observation input line of that estimator module not being in the third state:
i) in the event that the storage element comprised by that estimator module is in the third state:
A) putting the storage element comprised by that estimator module into the same state as the observation input line comprised by that estimator module; and
B) putting the observation input line comprised by a lower order neighboring estimator module, if any, into the third state;
ii) in the event that the storage element comprised by that estimator is not in the third state:
A) obtaining, from the random number generator comprised by that estimator, a random value;
B) performing a comparison, wherein performing the comparison comprises comparing the random value with the storage element comprised by that estimator module; and
C) selectively, based on the comparison:
I) putting the observation input line comprised by the lower order neighboring estimator module, if any, into the state of the observation input line comprised by that estimator module; or
II) putting a mismatch identification line comprised by the lowest order estimator module into a state of the random value, and putting the observation input line comprised by the lower order neighboring estimator module, if any, into the third state;
c) determining whether to update the denominator of the ratio for the data stream and updating the denominator of the ratio for the data stream are performed by activating the mismatch finding circuitry of one or more estimator modules, starting with the highest order estimator modules and proceeding through progressively lower order estimator modules until satisfaction of at least on condition from a group consisting of:
i) mismatch finding circuitry comprised by an estimator module having a storage element in the third state is activated;
ii) the mismatch finding circuitry comprised by the lowest order estimator module is activated; and
iii) the mismatch identification line comprised by the lowest order estimator module is put into a state other than the third state.

16. The method of claim 13, wherein:
a) the method comprises the highest order estimator module, based on receiving an observation input value on the observation line, putting the adjustment line comprised by the lowest order estimator module into a state of the observation input value;
b) determining whether to update the numerator of the ratio for the data stream by modifying one or more stored values which had been previously been set based on observations of the data stream comprises the lowest order estimator module, based on the adjustment line comprised by that estimator module not being in the third state and on the mismatch identification line comprised by that estimator module not being in the third state:
i) performing an adjustment comparison, wherein the adjustment comparison comprises comparing the adjustment line comprised by that estimator module and the mismatch identification line comprised by that estimator module;
ii) based on the adjustment comparison, selectively performing an act from:
A) putting an adjustment line comprised by a second from lowest order estimator module into the third state; and
B) activating adjustment circuitry comprised by that estimator module.

17. The method of claim 16, wherein:
a) each estimator module from the set of estimator modules comprises adjustment circuitry;
b) for each estimator module from the set of estimator modules, the adjustment circuitry comprised by that estimator module comprises circuitry to, in the event the adjustment line comprised by that estimator module is not in the third state:
i) in the event that the storage element comprised by that estimator module is in the first state, put the storage element comprised by that estimator module into the second state and perform a comparison of the modified storage element state with the adjustment line's state;
ii) in the event that the storage element comprised by that estimator module is in the second state, put the storage element comprised by that estimator module into the first state and perform the comparison of the modified storage element state with the adjustment line's state;
c) for each estimator module except the highest order estimator module, the adjustment circuitry comprised by that estimator module comprises circuitry to:
i) in the event that the storage element comprised by that estimator module is in the third state, put the adjustment line comprised by a neighboring higher order estimator module into a same state as the adjustment line comprised by that estimator module;
ii) in the event the comparison of the modified storage element state with the adjustment line's state indicates a match, put the adjustment line comprised by the neighboring higher order estimator module into the third state; and
iii) in the event the comparison of the modified storage element state with the adjustment line's state does not indicate a match, put the adjustment line comprised by the neighboring higher order estimator module into the same state as the adjustment line comprised by that estimator module;
and
d) updating the numerator of the ratio for the data stream by modifying one or more stored values which had previously been set based on observations of the data stream comprises activating the adjustment circuitry of the lowest order estimator module.

18. The method of claim 12, wherein:
a) each estimator module from the set of estimator modules has two neighboring estimator modules;
b) the highest order estimator module has a second highest order estimator module as one neighbor, and the lowest order estimator module as its other neighbor;
c) the lowest order estimator module has a second lowest order estimator module as one neighbor, and the highest order estimator module as its other neighbor; and
d) either estimator module other than the highest order estimator module and the lowest order estimator module has a higher order estimator module as one neighbor, and a lower order estimator module as its other neighbor.

19. The method of claim 18, wherein the set of estimator modules consists of six estimator modules.

20. The method of claim 12, wherein:
a) updating the numerator of the ratio for the data stream by modifying one or more stored values which had previously been set based on observations of the data stream comprises: conveying data from the lowest order estimator module to progressively higher order estimator modules via a first data line forming a first loop around the estimator modules; and
b) determining whether to update the denominator of the ratio for the data stream and updating the denominator of the ratio for the data stream comprise:
i) conveying data from the highest order estimator module to progressively lower order estimator modules until reaching the lowest order estimator module via a second data line forming a second loop around the estimator modules; and
ii) conveying data from an estimator module other than the highest order estimator module to the lowest order estimator module via third data line forming a third loop around the estimator modules.

21. The method of claim 12, further comprising generating a simulated data stream emulating the data stream based on, at each estimator module from the set of estimator modules:
a) performing an evaluation, wherein the evaluation is of whether a value of the storage element comprised that estimator module matches a value provided by the random number generator comprised by that estimator module; and
b) based on the evaluation, selectively place the value of the storage element comprised by that estimator module onto a data line forming a loop around the estimator modules.

22. The method of claim 12, wherein the highest order estimator module and the lowest order estimator module are a single estimator module.

23. A system comprising:
a) a computer configured to take observations of events in a data stream; and
b) means for probabilistically maintaining a ratio for the data stream based on event inputs from the computer.
